(19) United States
(12) Patent Application Publication
(10) Pub. No.: US 2026/0219592 A1
(43) Pub. Date: Jul. 30, 2026

(54) METHOD AND APPARATUS FOR MEASURING A TOPOGRAPHY OF A SURFACE OF AN OBJECT

(71) Applicant: ASML NETHERLANDS B.V., Veldhoven (NL)

(72) Inventors: Zarko ZOBENICA, Eindhoven (NL); Jan Arie DEN BOER, Zwijndrecht (NL); Peter Fernand William Jozef DENDAS, Koersel (BE); Mihaita POPINCIUC, Eindhoven (NL); Viktor TROGRLIC, Eindhoven (NL)

(73) Assignee: ASML NETHERLANDS B.V., Veldhoven (NL)

(21) Appl. No.: 19/146,632

(22) PCT Filed: Jan. 18, 2024
(86) PCT No.: PCT/EP2024/051121

§ 371 Date: Jul. 9, 2025

(30) Foreign Application Priority Data
Jan. 31, 2023 (EP) 23154103.8

(51) Int. Cl. G03F 9/00; G01B 11/06

(52) U.S. Cl. CPC G03F 9/7034; G01B 11/0608; G03F 9/7026

(57) ABSTRACT

A method of measuring a topography of a surface of an object, the method includes: forming a first image of a pattern on a beam spot region with a radiation beam; moving the object relative to the beam spot region; receiving a portion of the radiation beam reflected from the object and splitting the reflected radiation into first and second portions such that a first portion of the radiation, which corresponds to a first portion of the first image, is spatially separate from a second portion of the radiation, which corresponds to a second portion of the first image; determining an intensity of the first and second portions of the radiation; and determining a height of the object by combining the intensity of the first portion of the radiation determined at a first time and the intensity of the second portion of the radiation determined at a second time.

### CROSS-REFERENCE TO RELATED APPLICATION

The application claims priority of EP Application Serial No. 23154103.8 which was filed on 31 Jan. 2023 and which is incorporated herein in its entirety by reference.

### FIELD

The present invention relates to a method of measuring a topography of a surface of an object. The present invention also relates a corresponding apparatus for measuring a topography of a surface of an object. The present invention has particular application in the field of lithography. The object may be a substrate within a lithographic apparatus. Such a substrate may comprise a silicon wafer coated with a photoresist. The apparatus may be referred to as a level sensor and may form part of a lithographic apparatus. The present invention also relates to a lithographic exposure method which uses the method or apparatus for measuring a topography of a surface of a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Before exposure of a wafer to patterned radiation in a lithographic apparatus, a topography of the wafer may be determined using apparatus that may be referred to as a level sensor. This measurement of the topography of the wafer may be performed within the lithographic apparatus, for example once the wafer has been clamped to a wafer stage. This information can be used during subsequent exposure of the wafer in order to keep the part of the wafer that is being exposed in a plane of best focus.

It may be desirable to provide new methods and/or apparatus for determining a topography of a wafer that may at least partially address one or more problems associated with existing arrangements, whether identified herein or otherwise.

### SUMMARY

According to a first aspect of the present disclosure there is provided a method of measuring a topography of a surface of an object, the method comprising: forming a first image of a pattern on a beam spot region with a radiation beam; moving the object relative to the beam spot region; receiving a portion of the radiation beam reflected from the object and splitting the reflected radiation into first and second portions such that a first portion of the radiation, which corresponds to a first portion of the first image, is spatially separate from a second portion of the radiation, which corresponds to a second portion of the first image; determining an intensity of the first and second portions of the radiation; and determining a height of the object by combining the intensity of the first portion of the radiation determined at a first time and the intensity of the second portion of the radiation determined at a second time.

The method according to the first aspect is advantageous as now discussed.

As the height of the object varies, the position of at least part of the second image of the pattern will also vary and, in turn, this may result in a change in the relative values of the first and second intensities. For example, as the height of the object varies, the position of at least part of the second image of the pattern may vary relative to splitting optics arranged to split the reflected radiation into the first and second portions.

By splitting the reflected radiation into first and second portions and determining the height of the substrate by combining the intensities of the first and second portions, the determination of the height can be substantially independent of the intensity of the radiation beam. For example, the height may be determined as a differential measurement.

The method according to the first aspect is of a type wherein the reflected light is split into two portions that correspond to different portions of the first image (formed on the object). In general, there may be a spatial offset between the first and second portions of the first image (although the first and second portions may partially overlap spatially). The object being measured may have some variation of reflectivity across the surface. For example, the object may have a local region or feature that has a different reflectivity to surrounding parts of the surface. With such an arrangement, as said feature moves into (or out of) the beam spot region any spatial offset between the first and second portions of the first image will result in a difference in the first and second intensities that is due to the change in reflectivity (not a height of the object). If the first and second intensities as determined at any given time are combined then the resultant determination of the height of the object will, in general, contain an error due to any changes in reflectivity of the surface. This is because the first and second portions of the radiation reflect from different areas of the surface.

By combining the intensity of the first portion determined at a first time and the intensity of the second portion determined at a second time, the method according to the first aspect allows the method to ensure that the first and second portions correspond to radiation that is reflected from substantially the same portion of the object. Advantageously, this can prevent any steps or sudden changes in reflectivity of the object from affecting the determination of the height.

The object may be a substrate within a lithographic apparatus. Such a substrate may comprise a silicon wafer coated with a photoresist. The silicon wafer may comprise one or more layers than have previously been formed, for example using a lithographic process. In general, there will be a range of different materials and/or different densities of features across a surface of such wafers. This can lead to changes in the reflectivity of the wafer across its surface as different materials may absorb different fractions of the incident radiation and different densities of features can result in different amounts of scattering of the incident radiation. For example, 3D-NAND wafers may contain features that can give rise to up to a 50% reduction in the amount of specular reflection of radiation.

It will be appreciated that determining a height of the object comprises determining a height of the object relative to a reference height or position.

The first time and the second time may be selected, in dependence on the movement of the object relative to the beam spot region, such that the first and second portions of the radiation that are combined correspond to radiation that is reflected from substantially the same portion of the object.

It will be appreciated that the first image of the pattern is formed at the beam spot region (through which the object is moved). Since the reflected radiation is split such that first and second portions of the radiation correspond to different portions of the first image, at any given instant the first and second portions of the radiation correspond to radiation that is reflected from two different portions of the object.

In some embodiments, the first and second portions of the first image (which supply the first and second portions of the reflected radiation) may be spatially separate in a direction in which the object is moved. For such embodiments one or both of the first and second intensities may be temporally shifted before they are combined to determine the height. For example, a time delay may be applied to one of the first and second intensities before it is combined with the other of the first and second intensities.

A time difference between the first time and the second time may be given by a spatial offset between the first and second portions of the first image in a direction in which the object is moved relative to the beam spot region divided by a speed at which the object is moved relative to the beam spot region.

In some embodiments the first and second portions may partially overlap spatially. For such embodiments the spatial offset between the first and second portions of the image may be a spatial offset between a center of mass of each of the first and second portions of the image.

The pattern may comprise at least one feature and a time difference between the first time and the second time may be given by half of an extent of the or each feature in a direction in which the object is moved relative to the beam spot region divided by a speed at which the object is moved relative to the beam spot region.

The or each feature may be a line. The pattern may, for example, comprise at least one line. In some embodiments, the pattern may comprise a plurality of lines. The or each line may have a thickness, t, in the direction in which the object is moved relative to the beam spot region. A spatial offset between the first portion of the first image and the second portion of the second image may be half of this thickness (t/2). This can be converted into a time delay by dividing by a speed, s, of the object relative to the beam spot region. For embodiments wherein the pattern comprises a plurality of lines with a 50% duty cycle (i.e. a separation between the lines is also t) having a pitch, p, a spatial offset between the first portion of the first image and the second portion of the second image is a quarter of the pitch (p/4). Again, this can be converted into a time delay by dividing by a speed, s, of the object relative to the beam spot region.

Forming the first image of the pattern on the beam spot region may comprise providing a radiation beam; patterning the radiation beam with a patterning device; and projecting the patterned radiation onto the beam spot region using projection optics.

Moving the object relative to the beam spot region may comprise scanning the object relative to the beam spot region. Such scanning may be at a constant speed or velocity or at a variable velocity. As used herein scanning of an object is intended to mean continuous movement of the object. Alternatively, moving the object relative to the beam spot region may comprise stepping the object relative to the beam spot region. As used herein stepping of an object is intended to mean movement of the object in a plurality of successive (temporally separated) steps.

The object may be supported by a support such as a wafer stage within a lithographic apparatus. Moving the object relative to the beam spot region may comprise moving said support.

Splitting the reflected radiation into first and second portions may comprise forming a second image of the pattern on splitting optics and using the splitting optics to direct radiation from first and second portions of the second image so as to be spatially separate.

The position of the second image relative to the splitting optics may determine how much of the reflected radiation is directed to each of the first and second portions.

The intensity of the first and second portions of the radiation may be determined a plurality of times at a sampling frequency.

That is to say, the intensity of the first and second portions of the radiation may be determined a plurality of times, each determination temporally separated from a previous determination and a subsequent determination. The sampling frequency may be the inverse of a temporal separation between the start of one determination and the start of a subsequent determination.

The first time may coincide with one of the plurality of determinations of the intensities of the first and second portions of the radiation. The second time may coincide with another one of the plurality of determinations of the intensities of the first and second portions of the radiation.

For example, it may be that a desired time delay be applied to one of the first and second intensities before it is combined with the other of the first and second intensities that is an integer number of times the temporal separation between the start of one determination and the start of a subsequent determination.

At least one of the first time or second time may be between two of the plurality of determinations of the intensities of the first and second portions of the radiation and the method may comprise interpolating between said two of the plurality of determinations of the intensities of the first and second portions of the radiation.

For example, it may be that a desired time delay be applied to one of the first and second intensities before it is combined with the other of the first and second intensities that is an a non-integer number of times the temporal separation between the start of one determination and the start of a subsequent determination. For example, it may be desired to apply a time delay to the second intensity before it is combined with the first intensity which is a non-integer number of times the temporal separation between the start of one determination and the start of a subsequent determination. For such embodiments, the second intensity that is used in the determination of the height may be an intensity obtained by (for example linearly) interpolating between the two determinations that the time delay falls between.

The height of the object may be proportional to the difference between the first intensity and the second intensity.

For example, the height of the object may be determined as being proportional to the difference between the first intensity and the second intensity divided by the sum of the first intensity and the second intensity.

According to a second aspect of the present disclosure there is provided a lithographic exposure method comprising: measuring a topography of a surface of a substrate using the method according to the first aspect of the present disclosure; patterning a radiation beam using a patterning device; and projecting the patterned radiation onto the substrate so as to form an image of the patterning device on the substrate; wherein a position of the substrate while the patterned radiation is being projected onto the substrate is controlled in dependence on the measured topography of the surface of the substrate.

Advantageously, the measured topography of a surface of a substrate can be used to control a height of the substrate while it is being exposed to the patterned radiation, for example to keep the substrate in a plane of best focus for the image of the patterning device. It will be appreciated that the image of the patterning device formed on the substrate may be a diffraction limited image.

The lithographic exposure may be a scanning exposure such that: patterning a radiation beam using a patterning device may comprise moving the patterning device through the radiation beam; and projecting the patterned radiation onto the substrate so as to form an image of the patterning device on the substrate may comprise moving the substrate such that the image of the patterning device is generally stationary relative to the substrate.

That is, in order to image the pattern onto a target region of the substrate, the patterning device is moved or scanned through an illumination region in a scanning direction. It will be appreciated that the substrate is also scanned relative to an illumination region in the plane of the substrate. The movement of the substrate is such than an aerial image of the patterning device is static relative to the substrate and it will be appreciated that a direction and/or speed of the substrate may, in general, differ from that of the patterning device (for example if the image is inverted and/or if a reduction faction is applied by the projection system).

According to a third aspect of the present disclosure there is provided an apparatus for measuring a topography of a surface of an object, the apparatus comprising: a support for supporting an object; projection optics operable to form a first image of a pattern on a beam spot region with a radiation beam; a movement mechanism operable to move the support so as to move an object supported by the support through the beam spot region; detection optics operable to receive a portion of the radiation beam reflected from the object and to split the reflected radiation into first and second portions such that a first portion of the radiation, which corresponds to a first portion of the first image, is spatially separate from a second portion of the radiation, which corresponds to a second portion of the first image; a first detector arranged to determine an intensity of the of the first portion of the radiation; a second detector arranged to determine an intensity of the of the second portion of the radiation; and a controller operable to determining a height of the object by combining the intensity of the first portion of the radiation determined at a first time and the intensity of the second portion of the radiation determined at a second time.

The apparatus may be referred to as a level sensor. The apparatus may form part of a lithographic apparatus.

The apparatus according to the third aspect is advantageous as now discussed. Since the detection optics is operable to split the reflected radiation into first and second portions and the controller is operable to determine the height of the substrate by combining the intensities of the first and second portions, the determination of the height is substantially independent of the intensity of the radiation beam. For example, the height may be determined as a differential measurement. Furthermore, by combining the intensity of the first portion determined at a first time and the intensity of the second portion determined at a second time, the apparatus according to the third aspect allows for the execution of a method to ensure that the first and second portions correspond to radiation that reflected from substantially the same portion of the object. Advantageously, this can prevent any steps or sudden changes in reflectivity of the object from affecting the determination of the height.

The controller may be operable to implement a method according to the first aspect of the present disclosure.

The projection optics may comprise: a projection patterning device; and first imaging optics arranged to form an image of the projection patterning device on the beam spot region.

The projection patterning device may comprise a grating. The grating may comprise a plurality of lines. The lines may be of uniform thickness. The grating may have a 50% duty cycle.

The detection optics may comprise: splitting optics arranged to split the reflected radiation into first and second portions; and second imaging optics arranged to receive radiation reflected from an object supported by the support and to form a second image of the pattern on the splitting optics.

The first imaging optics may be generally equivalent to the second imaging optics.

The splitting optics, the beam spot region and the projection patterning device are all in optically conjugate planes. It will be appreciated that two planes are optically conjugate if all of the radiation passing through each distinct point in the first plane is imaged onto a distinct point in the second plane.

An image of the projection patterning device is formed on the splitting optics, the position of that image being indicative of a height of the object. In particular, a position of that image relative to the splitting optics is indicative of a height of the object. As explained above, the projection patterning device may comprise a grating comprising a plurality of lines. The splitting optics may comprise a plurality of prisms and the image of each line may be imaged onto one of the plurality of generally triangular prisms such that a first portion of the line is incident in a first surface of the prism and a second portion of the line is incident in a second surface of the prism. The first portion of the line is directed to the first detector and the second portion of the line is directed to the second detector. As the line moves relative to the prism (as a result of a change in height of the object), the amount of radiation directed to each of the detectors changes.

The first time and the second time may be such that the first and second portions of the radiation that are combined correspond to radiation that is reflected from substantially the same portion of the object.

In some embodiments, the first and second portions of the first image (which supply the first and second portions of the reflected radiation) may be spatially offset in a direction in which the object is moved. For such embodiments one or both of the first and second intensities may be temporally shifted before they are combined to determine the height. For example, a time delay may be applied to one of the first and second intensities before it is combined with the other of the first and second intensities.

The apparatus may further comprise a time shift module arranged to apply a time shift to a first signal indicative of the first intensity from the first detector and/or a second signal indicative of the second intensity from the second detector such that the first signal is indicative of the intensity of the first portion of the radiation determined at a first time and the second signal is indicative of the intensity of the second portion of the radiation determined at a second time.

The time shift module may be implemented using hardware, software or a combination of both. Implementing such a time shift module using hardware (for example in a data acquisition module) may allow for greater precision. Implementing such a time shift module using software (for example as an algorithm executed by the controller) may be a less expensive solution.

A time shift applied to one of the first and second signals may be given by a spatial offset between the first and second portions of the first image in a direction in which the object is moved relative to the beam spot region divided by a speed at which the object is moved relative to the beam spot region.

In some embodiments the first and second portions may partially overlap spatially. For such embodiments the spatial offset between the first and second portions of the image may be a spatial offset between a center of mass of each of the first and second portions of the image.

The pattern may comprise at least one feature and a time shift applied to one of the first and second signals may be given by half of an extent of the or each feature in a direction in which the object is moved relative to the beam spot region divided by a speed at which the object is moved relative to the beam spot region.

The or each feature may be a line. The pattern may, for example, comprise at least one line. In some embodiments, the pattern may comprise a plurality of lines. The or each line may have a thickness, t, in the direction in which the object is moved relative to the beam spot region. A spatial offset between the first portion of the first image and the second portion of the second image may be half of this thickness (t/2). This can be converted into a time delay by dividing by a speed, s, of the object relative to the beam spot region. For embodiments wherein the pattern comprises a plurality of lines with a 50% duty cycle (i.e. a separation between the lines is also t) having a pitch, p, a spatial offset between the first portion of the first image and the second portion of the second image is a quarter of the pitch (p/4). Again, this can be converted into a time delay by dividing by a speed, s, of the object relative to the beam spot region.

The first and second detectors may be arranged to determine the intensity of the first and second portions respectively a plurality of times at a sampling frequency.

That is to say, the first and second detectors are arranged such that the intensity of the first and second portions of the radiation may be determined a plurality of times, each determination temporally separated from a previous determination and a subsequent determination. The sampling frequency may be the inverse of a temporal separation between the start of one determination and the start of a subsequent determination.

The first time may coincide with one of the plurality of determinations of the intensities of the first and second portions of the radiation and the second time may coincide with another one of the plurality of determinations of the intensities of the first and second portions of the radiation.

For example, it may be that a desired time delay be applied to one of the first and second intensities before it is combined with the other of the first and second intensities that is an integer number of times the temporal separation between the start of one determination and the start of a subsequent determination.

In some embodiments, at least one of the first time or second time may be between two of the plurality of determinations of the intensities of the first and second portions of the radiation and the controller may be operable to interpolate between said two of the plurality of determinations of the intensities of the first and second portions of the radiation.

For example, it may be that a desired time delay be applied to one of the first and second intensities before it is combined with the other of the first and second intensities that is an a non-integer number of times the temporal separation between the start of one determination and the start of a subsequent determination. For example, it may be desired to apply a time delay to the second intensity before it is combined with the first intensity which is a non-integer number of times the temporal separation between the start of one determination and the start of a subsequent determination. For such embodiments, the second intensity that is used in the determination of the height may be an intensity obtained by (for example linearly) interpolating between the two determinations that the time delay falls between.

The apparatus may further comprise a radiation source operable to produce the radiation beam.

According to a fourth aspect of the present disclosure there is provided a lithographic apparatus comprising the apparatus according to the third aspect of the present disclosure.

The lithographic apparatus may further comprise: an illumination system operable to illuminate an illumination region; a support structure configured to support a patterning device such that the patterning device is positionable in the illumination region; a substrate table configured to support a substrate; and a projection system operable to form an image of a patterning device supported by the support structure on a substrate supported by the substrate table.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 is a schematic illustration of a level or height sensor which may form part of the lithographic apparatus shown in FIG. 1;

FIG. 3 is a schematic representation of a method of measuring a topography of a surface of an object (for example a substrate) according to an embodiment of the present disclosure;

FIG. 4 is a schematic view of a portion of a substrate, showing a beam spot region or measurement location; a first image of a pattern of a projection grating comprising two lines; and a first feature on the substrate that has a different reflectivity to the rest of the substrate;

FIG. 5A shows first and second intensities I₁, I₂ (determined using the method shown in FIG. 3), which comprise radiation from first and second portions of the first image shown in FIG. 4 respectively, as function of the position of the substrate in the y-direction;

FIG. 5B shows a height that is determined by combining the first and second intensities I₁, I₂ shown in FIG. 5A;

FIG. 6 is a schematic view of a portion of a substrate, showing a beam spot region or measurement location; a first image of a pattern of a projection grating comprising two lines; and a second feature on the substrate that has a different reflectivity to the rest of the substrate;

FIG. 7A shows first and second intensities I₁, I₂ (determined using the method shown in FIG. 3), which comprise radiation from first and second portions of the first image shown in FIG. 6 respectively, as function of the position of the substrate in the y-direction;

FIG. 7B shows a height that is determined by combining the first and second intensities I₁, I₂ shown in FIG. 7A;

FIG. 8 is a schematic representation of an interpolation method for applying a time shift to an intensity signal (before it is combined with another intensity signal) that is a non-integer number of times the temporal separation two measurements of the intensity signal;

FIG. 9 is a schematic representation of a lithographic exposure method according to an embodiment of the present disclosure; and

FIG. 10 is a schematic representation of an apparatus for measuring a topography of a surface of an object according to an embodiment of the present disclosure, which may form part of the lithographic apparatus shown in FIG. 1 and which may implement the method shown in FIG. 3.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

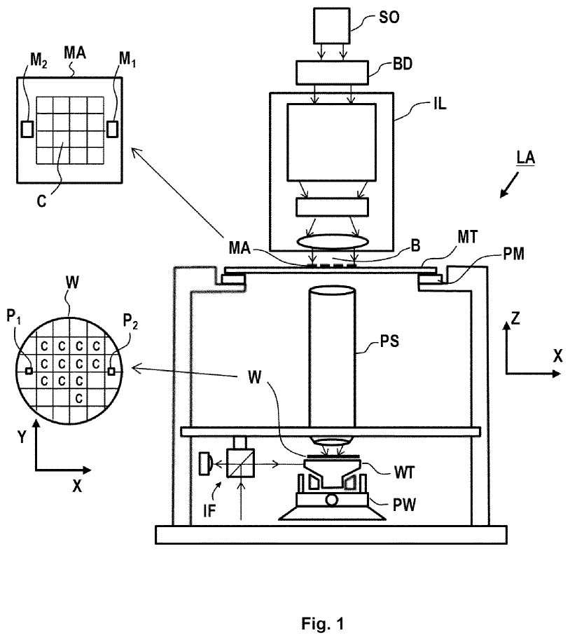

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W, on the other substrate support WT, is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions C. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

A topography measurement system, level sensor or height sensor, and which may be integrated in the lithographic apparatus, is arranged to measure a topography of a top surface of a substrate (or wafer). A map of the topography of the substrate, also referred to as height map, may be generated from these measurements indicating a height of the substrate as a function of the position on the substrate. This height map may subsequently be used to correct the position of the substrate during transfer of the pattern on the substrate, in order to provide an aerial image of the patterning device in focus on the substrate. It will be understood that “height” in this context refers to a dimension broadly out of the plane to the substrate (also referred to as Z-axis). Typically, the level or height sensor performs measurements at a fixed location (relative to its own optical system) and a relative movement between the substrate and the optical system of the level or height sensor results in height measurements at locations across the substrate.

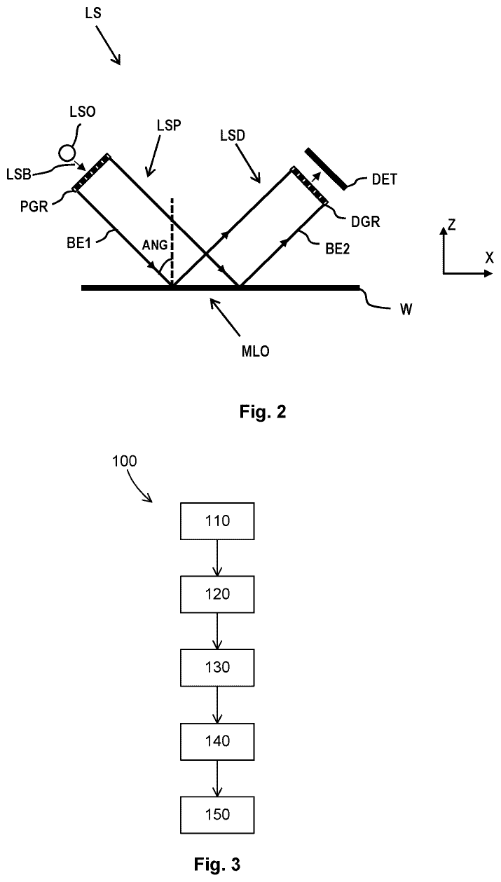

An example of a level or height sensor LS as known in the art is schematically shown in FIG. 2, which illustrates only the principles of operation. In this example, the level sensor LS comprises an optical system, which includes a projection unit LSP and a detection unit LSD. The projection unit LSP comprises a radiation source LSO providing a beam of radiation LSB which is imparted with a pattern by a projection grating PGR of the projection unit LSP. The projection grating PGR may alternatively be referred to as a patterning device PGR. The radiation source LSO may be, for example, a narrowband or broadband radiation source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate.

The projection grating PGR is a periodic grating comprising a periodic structure resulting in a beam of radiation BE1 having a periodically varying intensity. The beam of radiation BE1 with the periodically varying intensity is directed towards a measurement location MLO on a substrate W having an angle of incidence ANG with respect to an axis perpendicular (Z-axis) to the incident substrate surface between 0 degrees and 90 degrees, typically between 70 degrees and 80 degrees. The measurement location MLO may alternatively be referred to as the beam spot region MLO. At the measurement location MLO, the patterned beam of radiation BE1 is reflected by the substrate W (indicated by arrows BE2) and directed towards the detection unit LSD.

In order to determine the height level at the measurement location MLO, the level sensor further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as may be output by a photodetector, or representative of a spatial distribution of the intensity received, such as may be output by a camera or sensor array. The detector DET may comprise any combination of one or more detector types.

By means of triangulation techniques, the height level at the measurement location MLO can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas MLO or spots covering a larger measurement range.

Various height sensors of a general type are disclosed for example in U.S. Pat. Nos. 7,265,364 and 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

In general, the detection unit LSD may be arranged such that the reflected radiation BE2 is split into first and second portions and the height of the substrate W is determined by combining the intensities of the first and second portions. For example, the height may be determined as a differential measurement. Advantageously, with such an arrangement, the determination of the height of the substrate W can be substantially independent of the intensity of the radiation beam BE1. In practice, the splitting of the radiation into first and second portions may be achieved in a number of different ways.

For example, in some known arrangements, a combination of a polarizer and a shear plate (for example in the form of a Wollaston prism) are used to form two laterally shifted images of the projection grating PGR (each having a different polarization state) on a detection grating DGR. An example of such an arrangement is shown schematically in FIG. 5 of US2010233600A1. For example, the projection grating PGR may have a pitch P and a duty cycle of 50% such that the beam of radiation BE1 having a periodically varying intensity comprises a plurality of lines having a thickness of P/2, adjacent lines being separated by P/2. The polarizer and a shear plate are arranged to form two images of the projection grating PGR (each having a different polarization state) on the detection grating DGR, one image being laterally shifted relative to the other by P/2. Downstream of the detection grating DGR the two separate polarization states are each directed to a different detector. The height of the substrate W is determined as being proportional to the difference in the intensities of the two separate polarization states.

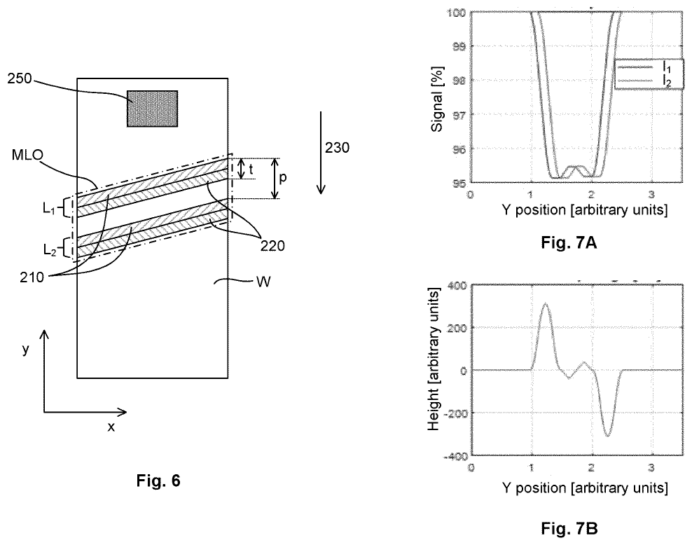

In some other known arrangements, rather than splitting the reflected radiation BE2 using two images of the projection grating PGR but having different polarization states, a single image of the projection grating PGR is formed on splitting optics that is arranged to split that single image into first and second portions. Examples of such arrangements are shown schematically in FIG. 6 of US2010233600A1 and FIG. 2 of WO2016102127A1. For example, such arrangements generally comprise splitting optics that is arranged to split the reflected radiation into first and second portions. The splitting optics may be a ruled grating with a triangular grating profile which acts as a series of wedges or prisms to redirect the reflected radiation BE2 (according to Snell's law). Such splitting optics may be considered to comprise a plurality of prisms and the image of each line of the projection grating PGR may be imaged onto one of the plurality of generally triangular prisms such that a first portion of the line is incident in a first surface of the prism and a second portion of the line is incident in a second surface of the prism. The first portion of the line is directed to the first detector and the second portion of the line is directed to the second detector. As the line moves relative to the prism (as a result of a change in height of the substrate W), the amount of radiation directed to each of the detectors changes. Embodiments of the present disclosure have particular application for level sensors using splitting optics of this type.

Some embodiments of the present disclosure relate to a method of measuring a topography of a surface of an object (for example a substrate W), as now discussed with reference to FIG. 3.

FIG. 3 is a schematic representation of a method 100 of measuring a topography of a surface of an object (for example a substrate W). The method 100 may, for example, be carried out using a level sensor LS generally of the form shown in FIG. 2.

The method 100 comprises a step 110 of forming a first image of a pattern on a beam spot region with a radiation beam. Forming the first image of the pattern on the beam spot region MLO may comprise providing a radiation beam LSB; patterning the radiation beam LSB with a patterning device (such as, for example, the projection grating PGR); and projecting the patterned radiation BE1 onto the beam spot MLO region using projection optics. For example, the projection unit LSP may be used to form a first image of the projection grating PGR (the pattern) on the measurement location MLO (the beam spot region) with the beam of radiation LSB.

The method 100 further comprises a step 120 of moving the object (for example the substrate W) relative to the beam spot region (for example the measurement location MLO). It will be appreciated that although described here as moving the object relative to the beam spot region in alternative embodiments the beam spot region may be moved relative to the object (for example by moving the projection unit LSP and the detection unit LSD while the object W remains stationary).

Moving the object W relative to the beam spot region MLO may comprise scanning the object W relative to the beam spot region MLO. Such scanning may be at a constant speed or velocity or at a variable velocity. As used herein scanning of an object W is intended to mean continuous movement of the object W. Alternatively, moving the object W relative to the beam spot region MLO may comprise stepping the object W relative to the beam spot region MLO. As used herein stepping of an object W is intended to mean movement of the object in a plurality of successive (temporally separated) steps.

The object W may be supported by a support such as a wafer stage WT within a lithographic apparatus LA. Moving the object W relative to the beam spot region MLO may comprise moving said support WT.

The method 100 further comprises a step 130 of receiving a portion of the radiation beam reflected from the object (for example reflected radiation BE2) and splitting the reflected radiation into first and second portions. In particular, the reflected radiation BE2 is split such that a first portion of the radiation BE2, which corresponds to a first portion of the first image (formed at the measurement location MLO), is spatially separate from a second portion of the radiation, which corresponds to a second portion of the first image.

The method 100 further comprises a step 140 of determining an intensity of the first and second portions of the radiation. For example, this step 140 may be performed by the detector DET which may comprise at least two portions, each one operable to determine an intensity of one of the first and second portions of the reflected radiation BE2.

The method 100 further comprises a step 150 of determining a height, h, of the object W by combining the intensity of the first portion I₁ of the radiation BE2 determined at a first time t₁ and the intensity of the second portion I₂ of the radiation BE2 determined at a second time t₂.

It will be appreciated that determining a height of the object W comprises determining a height of the object relative to a reference height or position, as is known in the art. The height, h, of the object W may be proportional to the difference between the first intensity determined at a first time I₁(t₁) and the second intensity I₂(t₁). For example, the height h of the object W may be determined as being proportional to the difference between the first intensity I₁(t₁) and the second intensity I₁(t₁) divided by the sum of the first intensity and the second intensity. That is, the height h may be given by:

$$h = α \cdot \frac{{I}_{2} ( {t}_{2} ) - {I}_{1} ( {t}_{1} )}{{I}_{2} ( {t}_{2} ) + {I}_{1} ( {t}_{1} )} \qquad ( 1 )$$

where a is a gain.

As the height of the object W varies, the position of at least a part of the a second image of the pattern PGR, for example formed at the detection grating DGR, will also vary and, in turn, this may result in a change in the relative values of the first and second intensities I₁, I₂. For example, as the height of the object W varies, the position of at least a part of the second image of the pattern PGR may vary relative to splitting optics arranged to split the reflected radiation into the first and second portions (or relative to a detector array).

By splitting the reflected radiation BE2 into first and second portions and determining the height of the substrate W by combining the intensities of the first and second portions, the determination of the height can be substantially independent of the intensity of the radiation beam LSB. For example, the height may be determined as a differential measurement (for example according to equation (1)).

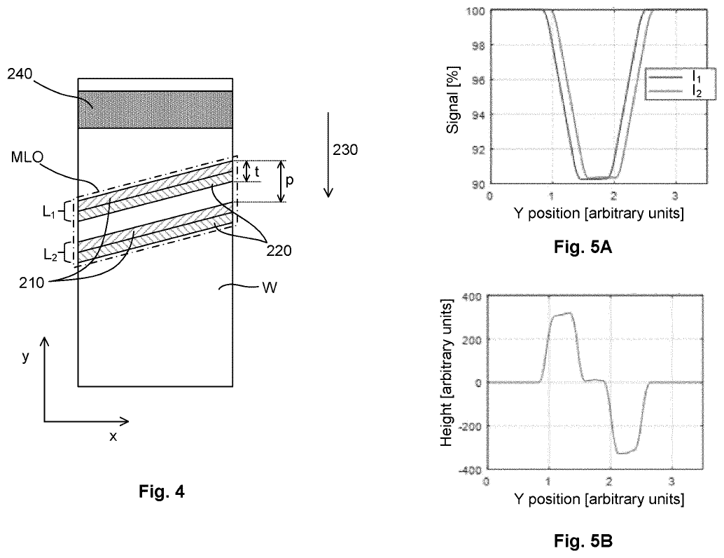

The method 100 shown in FIG. 3 is of a type wherein the reflected light BE2 is split into two portions that correspond to different portions of the first image (formed on the object W). The first image is formed in the beam spot region or the measurement location MLO. In general, there may be a spatial offset between the first and second portions of the first image (although the first and second portions may partially overlap spatially). The object W being measured may have some variation of reflectivity across the surface. For example, the object W may have a local region or feature that has a different reflectivity to surrounding parts of the surface. With such an arrangement, as said feature moves into (or out of) the beam spot region MLO (for example due to the relative movement at step 120) any spatial offset between the first and second portions of the first image will result in a difference in the first and second intensities that is due to the change in reflectivity (not a height of the object W). As discussed further below with reference to FIGS. 4 to 7B, if the first and second intensities as determined at any given time are combined then the resultant determination of the height of the object will, in general, contain an error due to any changes in reflectivity of the surface of the object W. This is because the first and second portions of the radiation reflect from different areas of the surface of the object W.

By combining the intensity of the first portion determined at a first time and the intensity of the second portion determined at a second time, the method 100 shown in FIG. 3 allows for the first and second portions to correspond to radiation that is reflected from substantially the same portion of the object W. Advantageously, this can prevent any steps or sudden changes in reflectivity of the object W from affecting the determination of the height.

As described above, the object may be a substrate W within a lithographic apparatus LA. Such a substrate W may comprise a silicon wafer coated with a photoresist. The silicon wafer may comprise one or more layers than have previously been formed, for example using a lithographic process. In general, there will be a range of different materials and/or different densities of features across a surface of such wafers W. This can lead to changes in the reflectivity of the wafer W across its surface as different materials may absorb different fractions of the incident radiation and different densities of features can result in different amounts of scattering of the incident radiation. For example, 3D-NAND wafers may contain features that can give rise to up to a 50% reduction in the amount of specular reflection of radiation.

Although the method 100 is shown in FIG. 3 as five separate steps 110, 120, 130, 140, 150 this is merely for ease of understanding and it will be appreciated that the steps may be performed in any order. For example, one may expect the step 110 of forming a first image of a pattern on a beam spot region with a radiation beam to be carried out before the step 130 of receiving a portion of the radiation beam reflected from the object and splitting the reflected radiation into first and second portions. However, in practice, the method 100 is particularly suited to measurement over an extended time period and therefore these steps may be concurrent. In one embodiment, all of the steps 110, 120, 130, 140, 150 shown in FIG. 3 are carried out concurrently during a measurement time.

FIG. 4 is a schematic view of a portion of a substrate W, showing the beam spot region or measurement location MLO. A first image of the pattern of the projection grating PGR comprising two lines L₁, L₂ is also shown. In addition, each of the two lines comprises two portions (the top half and bottom half respectively of each line L₁, L₂ in FIG. 4). The first image of the projection grating PGR may be considered to comprise a first portion 210 (comprising the top portions of the two lines L₁, L₂) and a second portion 220 (comprising the bottom portions of the two lines L₁, L₂).

The first and second portions 210, 220 of the first image correspond to first and second portions of radiation reflected by the substrate W that are split (at step 130 of the method 100 of FIG. 3), for example by splitting optics. That is, the first and second portions as indicated in FIG. 4 may be considered to be a projection of the division effected by the splitting optics back onto the substrate W (only indicated here to illustrate the advantages of the methods of embodiments of the present disclosure). In particular, the division of the first image into first and second portions 210, 220 that is shown in FIG. 4 represents the situation when the height of the substrate W is zero (relative to a reference height) as the first and second portions 210, 220 are of substantially equal size.

As indicated by arrow 230, during the method 100 (at step 120) the substrate W is moved relative to the beam spot region (measurement location MLO) in a scanning direction (the y-direction in FIG. 4). The x and y directions shown in FIG. 4 represent the sides of the target portions C (e.g., comprising one or more dies) of the substrate W (see FIG. 1) and, in general, features formed on the substrate tend to be aligned with the x and/or y directions. Note that the lines L₁, L₂ of the projection grating PGR are arranged at a non-zero angle to both the x and y directions in FIG. 4. This is to minimize the effects of scattering of the incident radiation beam BE1 from features on the substrate (other than specular reflection) on the height measurement.

Each of the two lines L₁, L₂ has a thickness, t, in the direction in which the substrate W is moved (i.e. the y-direction) relative to the beam spot region MLO. Note that the thickness t of each of the lines L₁, L₂ in the first image (formed on the substrate W) will in general be larger than a thickness of each of the corresponding lines on the projection grating PGR (by a factor of 1/cos(ANG)). A space between the two lines in the y-direction is also t such that the pitch p of the first image (in the y-direction) is 2t. There is a spatial offset between the first and second portions 210, 220 of the first image in the y-direction equal to t/2 (where t is the thickness t of the lines L₁, L₂).

Also shown in FIG. 4 is a feature 240 on the wafer W that has a different reflectivity to the rest of the substrate W. In particular, the feature 240 on the wafer W may have a reflectivity that is 80% of the rest of the substrate W. In this example, the feature 240 of reduced reflectivity has an extent in the x-direction that is equal to or greater than an extent of the beam spot region MLO. Therefore, the feature 240 may be considered to provide a one-dimensional step in reflectivity (in the y-direction). As the substrate is scanned or stepped in the y-direction, the feature 240 will move into, and subsequently move out of, the beam spot region MLO.

As the feature 240 moves into (or out of) the beam spot region MLO (for example due to the relative movement at step 120), the spatial offset between the first and second portions 210, 220 of the first image in the y-direction results in a difference in the first and second intensities (as determined at step 140) that is due to the change in reflectivity between feature 240 and the rest of the substrate W (and not due to a height of the object W). This can be seen from FIGS. 5A and 5B.

FIG. 5A shows the first and second intensities I₁, I₂ (determined at step 140), which comprises radiation from the first and second portions 210, 220 of the first image respectively, as function of the position of the substrate in the y-direction. It can be seen from FIG. 5A (moving from left to right in FIG. 5A) that as the feature 240 moves into the beam spot region MLO, the first intensity I₁ is reduced (due to the reduced reflectivity of feature 240) before the second intensity I₂ is reduced. Once the feature 240 is fully within the beam spot region MLO, the first and second intensities I₁, I₂ are both reduced due to the reduced reflectivity of feature 240. Furthermore, as the feature 240 moves out of the beam spot region MLO, the first intensity I₁ increases back to its nominal value before the second intensity I₂.

FIG. 5B shows a height that is determined by combining the first and second intensities I₁, I₂ as determined at any given time. In particular, the height is proportional to the difference I₂−I₁. Recall that this example shown in FIG. 4 represents the situation when the height of the substrate W is zero (relative to a reference height) as the first and second portions 210, 220 are of substantially equal size. As a result, when the feature 240 is not in the beam spot region MLO (left and right hand sides of FIGS. 5A and 5B) the height is zero. Furthermore, when the feature 240 is completely within the beam spot region MLO (central portion of FIGS. 5A and 5B) the height is close to zero. However, due to the change in reflectivity caused as the feature 240 moves into or out of the beam spot region 240, although the substrate is at height zero, as the feature 240 moves into (or out of) the beam spot region MLO (for example due to the relative movement at step 120) combining the two intensities as determined at the same time will result in a significant error in the determination of the height of the substrate W. This is because the first and second portions 210, 220 of the radiation reflect from different areas of the surface of the substrate W.

FIG. 6 is another schematic view of a portion of a substrate W, showing the beam spot region or measurement location MLO, the first image of the pattern of the projection grating PGR comprising two lines L₁, L₂ and a feature 250 having a different reflectivity to the rest of the substrate W. The only difference between the arrangement shown in FIG. 6 and that shown in FIG. 4 is that, in the example shown in FIG. 6, the feature 250 of reduced reflectivity has an extent in the x-direction that is less than an extent of the beam spot region MLO. Therefore, the feature 250 may be considered to provide a two-dimensional step in reflectivity (in the y-direction).

FIG. 7A shows the first and second intensities I₁, I₂ (determined at step 140), which comprises radiation from the first and second portions 210, 220 of the first image respectively, as function of the position of the substrate in the y-direction. FIG. 7B shows a height that is determined by combining the first and second intensities I₁, I₂ as determined at any given time.

In some embodiments, at step 150, the first time and the second time are selected, in dependence on the movement of the object W relative to the beam spot region MLO, such that the first and second portions of the radiation that are combined correspond to radiation that is reflected from substantially the same portion of the object W. It will be appreciated that the first image of the pattern is formed at the beam spot region MLO (through which the object W is moved). Since the reflected radiation is split such that first and second portions of the radiation correspond to different portions of the first image, at any given instant the first and second portions of the radiation correspond to radiation that is reflected from two different portions of the object W. In some embodiments, the first and second portions of the first image (which supply the first and second portions of the reflected radiation BE2) may be spatially separate in a direction in which the object is moved. For example, in the example arrangements shown in FIGS. 4 and 6, the first and second portions 210, 220 of the first image (which supply the first and second portions of the reflected radiation BE2) are spatially separate in the direction in which the object W is moved (the y-direction) by the thickness, t, of one of the two lines L₁, L₂. For such embodiments one or both of the first and second intensities may be temporally shifted before they are combined to determine the height. For example, a time delay may be applied to one of the first and second intensities before it is combined with the other of the first and second intensities.

In some embodiments, a time difference, Δt, between the first time and the second time is given by a spatial offset between the first and second portions of the first image in a direction in which the object W is moved relative to the beam spot region MLO divided by a speed at which the object W is moved relative to the beam spot region MLO. In some embodiments the first and second portions may partially overlap spatially (as is the case for the first and second portions 210, 220 of the first image in the examples shown in FIGS. 4 and 6). For such embodiments the spatial offset between the first and second portions of the image may be a spatial offset between a center of mass of each of the first and second portions of the image. For example, for the examples shown in FIGS. 4 and 6, the height may be determined according to equation (1) where:

$${t}_{2} = {t}_{1} - Δ t \qquad ( 2 )$$

and where:

$$Δ t = \frac{t / 2}{s} \qquad ( 3 )$$

and where t is the thickness of two lines L₁, L₂ in the first image (formed on the substrate W) in the direction in which the substrate W is moved (i.e. the y-direction) relative to the beam spot region MLO and s is the speed at which the object W is moved relative to the beam spot region MLO. Recall that the thickness t of each of the lines L₁, L₂ in the first image (formed on the substrate W) will in general be larger than a thickness of each of the corresponding lines on the projection grating PGR (by a factor of 1/cos(ANG)).

In some embodiments, the pattern comprises at least one feature (for example a line) and the time difference, Δt, between the first time and the second time is given by half of an extent of the or each feature in a direction in which the object W is moved relative to the beam spot region MLO divided by a speed at which the object W is moved relative to the beam spot region MLO. The or each feature may be a line. The pattern may, for example, comprise at least one line. In some embodiments, the pattern may comprise a plurality of lines. In the plane of the substrate W, the or each line may have a thickness, t, in the direction in which the object W is moved relative to the beam spot region MLO. A spatial offset between the first portion of the first image and the second portion of the second image may be half of this thickness (t/2). This can be converted into a time delay by dividing by a speed, s, of the object W relative to the beam spot region MLO. For embodiments wherein the pattern comprises a plurality of lines with a 50% duty cycle (i.e. a separation between the lines is also t) having a pitch, p, a spatial offset between the first portion of the first image and the second portion of the second image is a quarter of the pitch (p/4). Again, this can be converted into a time delay by dividing by a speed, s, of the object relative to the beam spot region MLO.

In some embodiments, splitting the reflected radiation BE2 into first and second portions may comprise forming a second image of the pattern on splitting optics (which may be arranged generally where the detection grating DGR is shown in FIG. 2) and using the splitting optics to direct radiation from first and second portions of the second image so as to be spatially separate. The position of the second image relative to the splitting optics may determine how much of the reflected radiation is directed to each of the first and second portions.

Alternatively, in some embodiments splitting the reflected radiation BE2 into first and second portions may comprise forming a second image of the pattern on a detector array comprising a plurality of sensing elements. The detector array may be referred to as a camera and the individual sensing elements may be referred to as pixels. With such an arrangement, a first subset of the sensing elements may be used to determine an intensity of the first portion of the radiation (at step 140) and a second subset of the sensing elements may be used to determine an intensity of the second portion of the radiation.

In some embodiments, the intensity of the first and second portions of the radiation may be determined a plurality of times at a sampling frequency, f. That is to say, the intensity of the first and second portions of the radiation may be determined a plurality of times, each determination temporally separated from a previous determination and a subsequent determination. The sampling frequency, f, may be the inverse of a temporal separation between the start of one determination and the start of a subsequent determination.

In some embodiments, the first time (at which the intensity of the first portion of the radiation BE2 is determined at step 150) coincides with one of the plurality of determinations of the intensities of the first and second portions of the radiation and the second time coincides (at which the intensity of the second portion of the radiation BE2 is determined at step 150) with another one of the plurality of determinations of the intensities of the first and second portions of the radiation. For example, it may be that a desired time delay be applied to one of the first and second intensities before it is combined with the other of the first and second intensities that is an integer number of times the temporal separation between the start of one determination and the start of a subsequent determination.

Alternatively, in some embodiments, at least one of the first time (at which the intensity of the first portion of the radiation BE2 is determined at step 150) or second time (at which the intensity of the second portion of the radiation BE2 is determined at step 150) is between two of the plurality of determinations of the intensities of the first and second portions of the radiation. For such embodiments, the method 100 may comprise interpolating between said two of the plurality of determinations of the intensities of the first and second portions of the radiation.

For example, it may be that a desired time shift be applied to one of the first and second intensities before it is combined with the other of the first and second intensities that is an a non-integer number of times the temporal separation between the start of one determination and the start of a subsequent determination. For example, it may be desired to apply a time delay Δt to the second intensity before it is combined with the first intensity (for example as defined by equations (2) and (3)) which is a non-integer number of times the temporal separation between the start of one determination and the start of a subsequent determination. For such embodiments, the second intensity that is used in the determination of the height may be an intensity obtained by (for example linearly) interpolating between the two determinations that the time delay falls between.

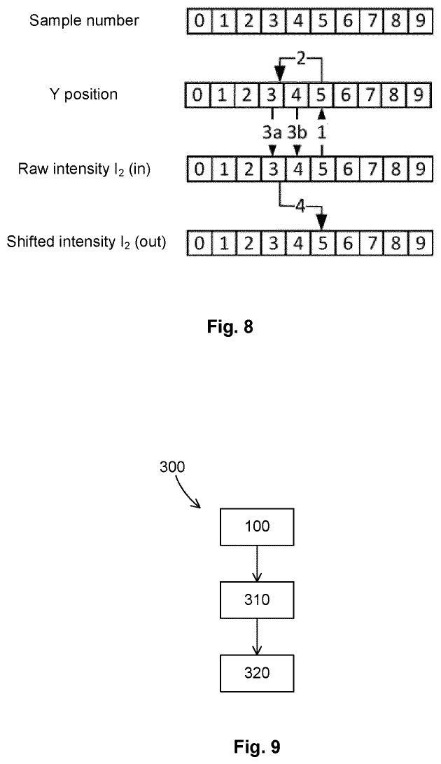

The time shift may be implemented using hardware, software or a combination of both. Implementing such a time shift using hardware (for example in a data acquisition module) may allow for greater precision. Implementing such a time shift module using software (for example as an algorithm executed by the controller) may be a less expensive solution. An example of a software implementation is now discussed with reference to FIG. 8.

There will, in general, be a plurality of samples (labelled as 0 to 9 in FIG. 8), which for each of the two intensities, I₁, I₂ are determined at a plurality of y-positions. In this example, a temporal shift is applied to one of the intensities, I₂, although it will be appreciated that alternatively a shift may be applied to the other intensity, or to both intensities.

For each sample, the following steps are preformed (explained with reference to sample number 5).

At step 1, for the sample, find the corresponding y-position, Y, in the y-position data.

At step 2, a shift is applied to this y-position, Y, so as to determine a shifted y-position, Y′. The samples in the y-position that this shifted y-position Y′ is in between are determined. In this example, the shifted y-position Y′ is in between sample number 3 and sample number 4. A ratio (a number between 0 and 1) is determined that quantifies where exactly the shifted y-position Y′ is between samples 3 and 4. For example a ratio of 0 would correspond to the y-position of sample 3, a ratio of 1 would correspond to the y-position of sample 4 and a ratio between 0 and 1 corresponds to a y-position between samples 3 and 4. Smaller ratios are closer to sample number 3 and larger ratios are closer to sample number 4.

The ratio, β, may be given by:

$$β = \frac{{y}^{′} - {y}_{n}}{{y}_{n + 1} - {y}_{n}} \qquad ( 4 )$$

where y′ is the shifted y-position, which has been determined to be between sample values yₙ and yₙ₊₁.

At step 3 (indicated schematically as 3a and 3b), the ratio β determined at step 2 is used to interpolate between the two corresponding samples 3 and 4 of the raw intensity that is input. That is, a shifted, or corrected, intensity I′ is determined by interpolation, for example according to:

$${I}^{′} = {I}_{n} + β \cdot ( {I}_{n + 1} - {I}_{n} ) \qquad ( 5 )$$

where Iₙ and Iₙ₊₁ are the two raw intensity values (input) that correspond to the two y-position sample values yₙ and yₙ₊₁ that the shifted y-position is between.

At step 4, this interpolated intensity value I′ is stored as the shifted output intensity value for sample number 5. This shifted second intensity I₂ data set can now be combined with the raw first intensity I₁ data set but combining the nth data values for each and, due to the interpolation and shifting process described above, this is equivalent to combining the intensity of the first portion I₁ of the radiation determined at a first time t₁ and the intensity of the second portion I₂ of the radiation determined at a second time t₂.

In case the shifted y-position Y′ is outside the y-position data array, the shifted intensity value will be invalid. This may be the case, for example, in FIG. 8 if Y′ is determined to be less than sample number 0. Optionally, for such cases the shifted y-position Y′ may be equated to the closest y-position in the data array (for example sample number 0 if Y′ is determined to be less than sample number 0).

Some embodiments of the present disclosure relate to lithographic exposure methods. An example of such a lithographic exposure method 300 is shown schematically in FIG. 9. The lithographic exposure method 300 comprises measuring a topography of a surface of a substrate W using the method 100 of FIG. 3. The lithographic exposure method 300 further comprises: a step 310 of patterning a radiation beam B using a patterning device MA; and a step 320 of projecting the patterned radiation onto the substrate W so as to form an image of the patterning device MA on the substrate W. A position of the substrate W while the patterned radiation is being projected onto the substrate W (at step 320) is controlled in dependence on the measured topography of the surface of the substrate W (as measured at step 100).

Advantageously, the measured topography of a surface of a substrate can be used to control a height of the substrate W while it is being exposed to the patterned radiation, for example to keep the substrate W in a plane of best focus for the image of the patterning device MA. It will be appreciated that the image of the patterning device MA formed on the substrate W may be a diffraction limited image.

In some embodiments, the lithographic exposure method 300 comprises a scanning exposure such that patterning a radiation beam using a patterning device MA comprises moving the patterning device MA through the radiation beam B and projecting the patterned radiation onto the substrate W so as to form an image of the patterning device MA on the substrate W and comprises moving the substrate W such that the image of the patterning device MA is generally stationary relative to the substrate W. That is, in order to image the pattern onto a target region C of the substrate W, the patterning device MA is moved or scanned through an illumination region in a scanning direction. It will be appreciated that the substrate W is also scanned relative to an illumination region in the plane of the substrate W. The movement of the substrate W is such than an aerial image of the patterning device MA is static relative to the substrate W and it will be appreciated that a direction and/or speed of the substrate W may, in general, differ from that of the patterning device MA (for example if the image is inverted and/or if a reduction faction is applied by the projection system PS).

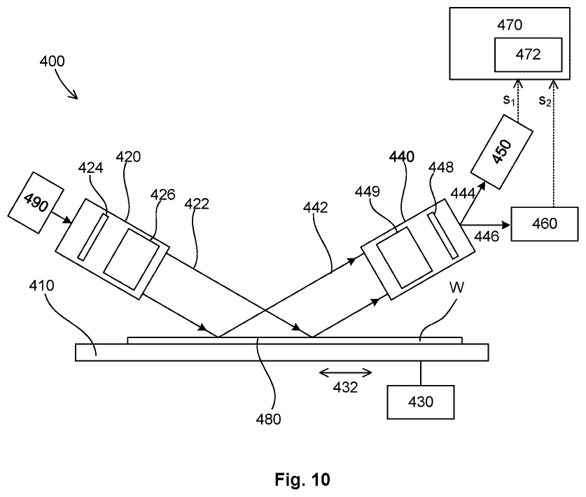

Some embodiments of the present disclosure relate to an apparatus for measuring a topography of a surface of an object W. An embodiment of such an apparatus 400 is shown in FIG. 10. The apparatus 100 may be referred to as a level sensor. The apparatus 100 may form part of a lithographic apparatus LA of the type shown in FIG. 1 and described above. The apparatus 400 is generally of the form of the level sensor LS shown in FIG. 2.

The apparatus 400 comprises: a support 410; projection optics 420; a movement mechanism 430; detection optics 440; a first detector 450; a second detector 460 and a controller 470.

The support 410 is suitable for supporting an object W. The support 410 may, for example, comprise a substrate table WT.

The projection optics 420 is operable to form a first image of a pattern on a beam spot region 480 with a radiation beam 422. The projection optics 420 is generally equivalent to the projection unit LSP shown in FIG. 2 and described above and the beam spot region 480 may be generally equivalent to the measurement location MLO shown in FIG. 2 and described above. The projection optics 420 may, for example, comprise: a projection patterning device 424; and first imaging optics 426 arranged to form an image of the projection patterning device 424 on the beam spot region 480. The projection patterning device 424 may comprise a grating. The grating may comprise a plurality of lines. The lines may be of uniform thickness. The grating may have a 50% duty cycle. The projection patterning device 424 may be generally equivalent to the projection grating PGR shown in FIG. 2 and described above.

The movement mechanism 430 is operable to move the support 410 so as to move an object (for example a substrate W) supported by the support 410 through the beam spot region 480. This movement is indicated schematically by arrow 432.

The detection optics 440 are operable to receive a portion 442 of the radiation beam reflected from the object W and to split the reflected radiation 442 into first and second portions 444, 446 such that a first portion 444 of the radiation, which corresponds to a first portion of the first image, is spatially separate from a second portion 446 of the radiation, which corresponds to a second portion of the first image. The detection optics 440 is generally equivalent to the detection unit LSD shown in FIG. 2 and described above.

The first detector 450 is arranged to determine an intensity of the first portion 444 of the reflected radiation. The second detector 460 is arranged to determine an intensity of the second portion 446 of the reflected radiation.

The detection optics may comprise: splitting optics 448 arranged to split the reflected radiation 442 into first and second portions 444, 446; and second imaging optics 449 arranged to receive radiation 442 reflected from an object W supported by the support 410 and to form a second image of the pattern on the splitting optics 448. The first imaging optics 426 may be generally equivalent to the second imaging optics 449.

The splitting optics 448, the beam spot region 480 and the projection patterning device 424 are all in optically conjugate planes. It will be appreciated that two planes are optically conjugate if all of the radiation passing through each distinct point in the first plane is imaged onto a distinct point in the second plane.

An image of the projection patterning device 424 is formed on the splitting optics 448, the position of that image being indicative of a height of the object W. In particular, a position of that image relative to the splitting optics 448 is indicative of a height of the object W. As explained above, the projection patterning device 424 may comprise a grating comprising a plurality of lines. The splitting optics 448 may comprise a plurality of prisms and the image of each line may be imaged onto one of the plurality of generally triangular prisms such that a first portion of the line is incident in a first surface of the prism and a second portion of the line is incident in a second surface of the prism. The first portion of the line is directed to the first detector 450 and the second portion of the line is directed to the second detector 460. As the line moves relative to the prism (as a result of a change in height of the object W), the amount of radiation directed to each of the detectors 450, 460 changes.

Alternatively, in some embodiments splitting the reflected radiation 442 into first and second portions 444, 446 may comprise forming a second image of the pattern (for example using the second imaging optics 449) on a detector array comprising a plurality of sensing elements. The detector array may be referred to as a camera and the individual sensing elements may be referred to as pixels. With such an arrangement, a first subset of the sensing elements may be used to determine an intensity of the first portion of the radiation (at step 140) and a second subset of the sensing elements may be used to determine an intensity of the second portion of the radiation. Note that with such an arrangement (wherein the splitting optics 448, the first detector 450 and the second detector 460 are replaced by a detector array) the detection optics 440 may be considered to be operable to receive a portion 442 of the radiation beam reflected from the object W and to split the reflected radiation 442 into first and second portions 444, 446 such that a first portion 444 of the radiation, which corresponds to a first portion of the first image, is spatially separate from a second portion 446 of the radiation, which corresponds to a second portion of the first image by virtue of the forming the second image of the pattern (for example using the second imaging optics 449).

The controller 470 is operable to determine a height of the object W by combining the intensity of the first portion 444 of the reflected radiation determined at a first time t₁ and the intensity of the second portion 446 of the reflected radiation determined at a second time t₂.

The apparatus 400 shown in FIG. 10 is advantageous as now discussed. Since the detection optics 440 is operable to split the reflected radiation into first and second portions 444, 446 and the controller 470 is operable to determine the height of the substrate W by combining the intensities of the first and second portions 444, 446, the determination of the height is substantially independent of the intensity of the radiation beam 422. For example, the height may be determined as a differential measurement (for example according to equation (1)). Furthermore, by combining the intensity of the first portion 444 determined at a first time t₁ and the intensity of the second portion 446 determined at a second time t₂, the apparatus 400 shown in FIG. 4 allows for the execution of a method to ensure that the first and second portions 444, 446 correspond to radiation that is reflected from substantially the same portion of the object W. Advantageously, this can prevent any steps or sudden changes in reflectivity of the object W from affecting the determination of the height. The controller may be operable to implement the method of FIG. 3, as discussed above.

In some embodiments, the first time t₁ and the second time t₂ are such that the first and second portions 444, 446 of the radiation that are combined correspond to radiation that is reflected from substantially the same portion of the object W. In some embodiments, the first and second portions of the first image (which supply the first and second portions of the reflected radiation) may be spatially offset in a direction in which the object W is moved. For such embodiments, one or both of the first and second intensities may be temporally shifted before they are combined to determine the height. For example, a time delay may be applied to one of the first and second intensities before it is combined with the other of the first and second intensities.

In some embodiments, the apparatus 400 may further comprise a time shift module 472 that is arranged to apply a time shift to a first signal s₁ indicative of the first intensity from the first detector 450 and/or a second signal s₂ indicative of the second intensity from the second detector 460 such that the first signal s₁ is indicative of the intensity of the first portion 444 of the radiation determined at a first time t₁ and the second signal s₂ is indicative of the intensity of the second portion of the radiation determined at a second time t₂.

The time shift module 472 may be implemented using hardware, software or a combination of both. Implementing such a time shift module 472 using hardware (for example in a data acquisition module) may allow for greater precision. Implementing such a time shift module 472 using software (for example as an algorithm executed by the controller 470) may be a less expensive solution.

In some embodiments, a time shift applied to one of the first and second signals 444, 446 is given by a spatial offset between the first and second portions of the first image in a direction in which the object W is moved relative to the beam spot region 480 divided by a speed at which the object W is moved relative to the beam spot region 480. In some embodiments, the first and second portions may partially overlap spatially. For such embodiments the spatial offset between the first and second portions of the image may be a spatial offset between a center of mass of each of the first and second portions of the image.

In some embodiments, the pattern comprises at least one feature and wherein a time shift Δt applied to one of the first and second signals s₁, s₂ is given by half of an extent of the or each feature in a direction in which the object W is moved relative to the beam spot region 480 divided by a speed at which the object W is moved relative to the beam spot region 480. The or each feature may be a line. The pattern may, for example, comprise at least one line. In some embodiments, the pattern may comprise a plurality of lines. The or each line may have a thickness, t, in the direction in which the object W is moved relative to the beam spot region 480. A spatial offset between the first portion of the first image and the second portion of the second image may be half of this thickness (t/2). This can be converted into a time delay by dividing by a speed, s, of the object W relative to the beam spot region 480. For embodiments wherein the pattern comprises a plurality of lines with a 50% duty cycle (i.e. a separation between the lines is also t) having a pitch, p, a spatial offset between the first portion of the first image and the second portion of the second image is a quarter of the pitch (p/4). Again, this can be converted into a time delay by dividing by a speed, s, of the object W relative to the beam spot region 480.

In some embodiments, the first and second detectors 450, 460 are arranged to determine the intensity of the first and second portions 444, 446 respectively a plurality of times at a sampling frequency, f. That is to say, the first and second detectors 450, 460 may be arranged such that the intensity of the first and second portions 444, 446 of the radiation may be determined a plurality of times, each determination temporally separated from a previous determination and a subsequent determination. The sampling frequency, f, may be the inverse of a temporal separation between the start of one determination and the start of a subsequent determination.

For such embodiments, the first time t₁ may coincide with one of the plurality of determinations of the intensities of the first and second portions 444, 446 of the radiation and the second time may coincide with another one of the plurality of determinations of the intensities of the first and second portions 444, 446 of the radiation. For example, it may be that a desired time delay Δt is applied to one of the first and second intensities before it is combined with the other of the first and second intensities that is an integer number of times the temporal separation between the start of one determination and the start of a subsequent determination.

Alternatively, in some other embodiments, at least one of the first time t₁ or second time t₂ is between two of the plurality of determinations of the intensities of the first and second portions 444, 446 of the radiation and the controller 470 is operable to interpolate between said two of the plurality of determinations of the intensities of the first and second portions 444, 446 of the radiation.

For example, it may be that a desired time delay be applied to one of the first and second intensities before it is combined with the other of the first and second intensities that is a non-integer number of times the temporal separation between the start of one determination and the start of a subsequent determination. For example, it may be desired to apply a time delay to the second intensity before it is combined with the first intensity which is a non-integer number of times the temporal separation between the start of one determination and the start of a subsequent determination. For such embodiments, the second intensity that is used in the determination of the height may be an intensity obtained by (for example linearly) interpolating between the two determinations that the time delay falls between. Such interpolation may be generally as described above with reference to FIG. 8.

In some embodiments, the apparatus 400 may further comprise a radiation source 490 operable to produce the radiation beam 422.

Some embodiments of the present disclosure relate to a lithographic apparatus comprising the apparatus 400 of the type shown in FIG. 10. The lithographic apparatus may be of the type shown in FIG. 1. The lithographic apparatus LA may further comprise: an illumination system IL operable to illuminate an illumination region; a support structure MT configured to support a patterning device MA such that the patterning device MA is positionable in the illumination region; a substrate table WT configured to support a substrate W; and a projection system PS operable to form an image of a patterning device MA supported by the support structure MT on a substrate W supported by the substrate table WT.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. A method of measuring a topography of a surface of an object, the method comprising:
   forming a first image of a pattern on a beam spot region with a radiation beam;
   moving the object relative to the beam spot region;
   receiving a portion of the radiation beam reflected from the object and splitting the reflected radiation into first and second portions such that a first portion of the radiation, which corresponds to a first portion of the first image, is spatially separate from a second portion of the radiation, which corresponds to a second portion of the first image;
   determining an intensity of the first and second portions of the radiation; and
   determining a height of the object by combining the intensity of the first portion of the radiation determined at a first time and the intensity of the second portion of the radiation determined at a second time.
2. The method of clause 1 wherein the first time and the second time are selected, in dependence on the movement of the object relative to the beam spot region, such that the first and second portions of the radiation that are combined correspond to radiation that is reflected from substantially the same portion of the object.
3. The method of clause 1 or clause 2 wherein a time difference between the first time and the second time is given by a spatial offset between the first and second portions of the first image in a direction in which the object is moved relative to the beam spot region divided by a speed at which the object is moved relative to the beam spot region.
4. The method of any preceding clause wherein the pattern comprises at least one feature and wherein a time difference between the first time and the second time is given by half of an extent of the or each feature in a direction in which the object is moved relative to the beam spot region divided by a speed at which the object is moved relative to the beam spot region.
5. The method of any preceding clause wherein splitting the reflected radiation into first and second portions comprises forming a second image of the pattern on splitting optics and using the splitting optics to direct radiation from first and second portions of the second image so as to be spatially separate.
6. The method of any preceding clause wherein the intensity of the first and second portions of the radiation is determined a plurality of times at a sampling frequency.
7. The method of clause 6 wherein the first time coincides with one of the plurality of determinations of the intensities of the first and second portions of the radiation and the second time coincides with another one of the plurality of determinations of the intensities of the first and second portions of the radiation.
8. The method of clause 6 wherein at least one of the first time or second time is between two of the plurality of determinations of the intensities of the first and second portions of the radiation and wherein the method comprises interpolating between said two of the plurality of determinations of the intensities of the first and second portions of the radiation.
9. The method of any preceding clause wherein the height of the object is proportional to the difference between the first intensity and the second intensity.
10. A lithographic exposure method comprising:
   measuring a topography of a surface of a substrate using the method of any preceding clause;
   patterning a radiation beam using a patterning device; and
   projecting the patterned radiation onto the substrate so as to form an image of the patterning device on the substrate;
   wherein a position of the substrate while the patterned radiation is being projected onto the substrate is controlled in dependence on the measured topography of the surface of the substrate.
11. The lithographic exposure method of clause 10, wherein the lithographic exposure is a scanning exposure such that patterning a radiation beam using a patterning device comprises moving the patterning device through the radiation beam and projecting the patterned radiation onto the substrate so as to form an image of the patterning device on the substrate comprises moving the substrate such that the image of the patterning device is generally stationary relative to the substrate.
12. An apparatus for measuring a topography of a surface of an object, the apparatus comprising:
   a support for supporting an object;
   projection optics operable to form a first image of a pattern on a beam spot region with a radiation beam;
   a movement mechanism operable to move the support so as to move an object supported by the support through the beam spot region;
   detection optics operable to receive a portion of the radiation beam reflected from the object and to split the reflected radiation into first and second portions such that a first portion of the radiation, which corresponds to a first portion of the first image, is spatially separate from a second portion of the radiation, which corresponds to a second portion of the first image;
   a first detector arranged to determine an intensity of the of the first portion of the radiation;
   a second detector arranged to determine an intensity of the of the second portion of the radiation; and
   a controller operable to determining a height of the object by combining the intensity of the first portion of the radiation determined at a first time and the intensity of the second portion of the radiation determined at a second time.
13. The apparatus of clause 12 wherein the controller is operable to implement the method of any one of clauses 1 to 9.
14. The apparatus of clause 12 or clause 13 wherein the projection optics comprises:
   a projection patterning device; and
   first imaging optics arranged to form an image of the projection patterning device on the beam spot region.
15. The apparatus of any one of clauses 12 to 14 wherein the detection optics comprises:
   splitting optics arranged to split the reflected radiation into first and second portions; and
   second imaging optics arranged to receive radiation reflected from an object supported by the support and to form a second image of the pattern on the splitting optics.
16. The apparatus of any one of clauses 12 to 15 wherein the first time and the second time are such that the first and second portions of the radiation that are combined correspond to radiation that is reflected from substantially the same portion of the object.
17. The apparatus of any one of clauses 12 to 16 further comprising a time shift module arranged to apply a time shift to a first signal indicative of the first intensity from the first detector and/or a second signal indicative of the second intensity from the second detector such that the first signal is indicative of the intensity of the first portion of the radiation determined at a first time and the second signal is indicative of the intensity of the second portion of the radiation determined at a second time.
18. The apparatus of clause 17 wherein a time shift applied to one of the first and second signals is given by a spatial offset between the first and second portions of the first image in a direction in which the object is moved relative to the beam spot region divided by a speed at which the object is moved relative to the beam spot region.
19. The apparatus of clause 17 or clause 18 wherein the pattern comprises at least one feature and wherein a time shift applied to one of the first and second signals is given by half of an extent of the or each feature in a direction in which the object is moved relative to the beam spot region divided by a speed at which the object is moved relative to the beam spot region.
20. The apparatus of any one of clauses 12 to 19 wherein the first and second detectors are arranged to determine the intensity of the first and second portions respectively a plurality of times at a sampling frequency.
21. The apparatus of clause 20 wherein the first time coincides with one of the plurality of determinations of the intensities of the first and second portions of the radiation and the second time coincides with another one of the plurality of determinations of the intensities of the first and second portions of the radiation.
22. The apparatus of clause 20 wherein at least one of the first time or second time is between two of the plurality of determinations of the intensities of the first and second portions of the radiation and wherein the controller is operable to interpolate between said two of the plurality of determinations of the intensities of the first and second portions of the radiation.
23. The apparatus of any one of clauses 11 to 22 further comprising a radiation source operable to produce the radiation beam.
24. A lithographic apparatus comprising the apparatus of any one of clauses 11 to 23.

1. A method of measuring a topography of a surface of an object, the method comprising:
forming a first image of a pattern on a beam spot region with a radiation beam;
moving the object relative to the beam spot region;
receiving a portion of the radiation beam reflected from the object and splitting the reflected radiation into first and second portions such that a first portion of the radiation, which corresponds to a first portion of the first image, is spatially separate from a second portion of the radiation, which corresponds to a second portion of the first image;
determining an intensity of the first and second portions of the radiation; and
determining a height of the object by combining the intensity of the first portion of the radiation determined at a first time and the intensity of the second portion of the radiation determined at a second time.

2. The method of claim 1, wherein the first time and the second time are selected, in dependence on the movement of the object relative to the beam spot region, such that the first and second portions of the radiation that are combined correspond to radiation that is reflected from substantially the same portion of the object.

3. The method of claim 1, wherein a time difference between the first time and the second time is given by a spatial offset between the first and second portions of the first image in a direction in which the object is moved relative to the beam spot region divided by a speed at which the object is moved relative to the beam spot region.

4. The method of claim 1, wherein the pattern comprises at least one feature and wherein a time difference between the first time and the second time is given by half of an extent of the or each feature in a direction in which the object is moved relative to the beam spot region divided by a speed at which the object is moved relative to the beam spot region.

5. The method of claim 1, wherein splitting the reflected radiation into first and second portions comprises forming a second image of the pattern on splitting optics and using the splitting optics to direct radiation from first and second portions of the second image so as to be spatially separate.

6. The method of claim 1, wherein the intensity of the first and second portions of the radiation is determined a plurality of times at a sampling frequency.

7. The method of claim 6, wherein the first time coincides with one of the plurality of determinations of the intensities of the first and second portions of the radiation and the second time coincides with another one of the plurality of determinations of the intensities of the first and second portions of the radiation.

8. The method of claim 6, wherein the first time and/or second time is between two determinations of the plurality of determinations of the intensities of the first and second portions of the radiation and further comprising interpolating between the two determinations of the plurality of determinations of the intensities of the first and second portions of the radiation.

9. An apparatus for measuring a topography of a surface of an object, the apparatus comprising:
projection optics configured to form a first image of a pattern on a beam spot region with a radiation beam;
a movement mechanism configured operable to move an object through the beam spot region;
detection optics configured to receive a portion of the radiation beam reflected from the object and to split the reflected radiation into first and second portions such that a first portion of the radiation, which corresponds to a first portion of the first image, is spatially separate from a second portion of the radiation, which corresponds to a second portion of the first image;
a first detector arranged to determine an intensity of the first portion of the radiation;
a second detector arranged to determine an intensity of the second portion of the radiation; and
a controller configured to determining a height of the object by combining the intensity of the first portion of the radiation determined at a first time and the intensity of the second portion of the radiation determined at a second time.

10. The apparatus of claim 9, wherein the projection optics comprises:
a projection patterning device; and
imaging optics arranged to form an image of the projection patterning device on the beam spot region.

11. The apparatus of claim 9, wherein the detection optics comprises:
splitting optics arranged to split the reflected radiation into first and second portions; and
imaging optics arranged to receive radiation reflected from an object supported by the support and to form a second image of the pattern on the splitting optics.

12. The apparatus of claim 9, wherein the first time and the second time are such that the first and second portions of the radiation that are combined correspond to radiation that is reflected from substantially the same portion of the object.

13. The apparatus of claim 9, further comprising a time shift module arranged to apply a time shift to a first signal indicative of the first intensity from the first detector and/or a second signal indicative of the second intensity from the second detector, such that the first signal is indicative of the intensity of the first portion of the radiation determined at a first time and the second signal is indicative of the intensity of the second portion of the radiation determined at a second time.

14. The apparatus of claim 13, wherein a time shift applied to the first or second signal is given by a spatial offset between the first and second portions of the first image in a direction in which the object is moved relative to the beam spot region divided by a speed at which the object is moved relative to the beam spot region.

15. The apparatus of claim 9, wherein the first and second detectors are arranged to determine the intensity of the first and second portions respectively a plurality of times at a sampling frequency.

16. A non-transitory computer-readable medium comprising instructions therein, the instructions, when executed by a processor system, configured to cause the processor system to at least:
obtain an intensity of first and second portions of radiation, wherein the first and second portions are obtained by formation of a first image of a pattern on a beam spot region with a radiation beam, movement of the object relative to the beam spot region, and splitting of reflected radiation from the object into the first and second portions such that the first portion of the radiation, which corresponds to a first portion of the first image, is spatially separate from a second portion of the radiation, which corresponds to a second portion of the first image; and
determine a height of the object by combining the intensity of the first portion of the radiation determined at a first time and the intensity of the second portion of the radiation determined at a second time.

17. The computer-readable medium of claim 16, wherein the first time and the second time were selected, in dependence on the movement of the object relative to the beam spot region, such that the first and second portions of the radiation that are combined correspond to radiation that is reflected from substantially the same portion of the object.

18. The computer-readable medium of claim 16, wherein a time difference between the first time and the second time was given by a spatial offset between the first and second portions of the first image in a direction in which the object is moved relative to the beam spot region divided by a speed at which the object is moved relative to the beam spot region.

19. The computer-readable medium of claim 16, wherein the pattern comprises at least one feature and wherein a time difference between the first time and the second time was given by half of an extent of the or each feature in a direction in which the object is moved relative to the beam spot region divided by a speed at which the object is moved relative to the beam spot region.

20. The computer-readable medium of claim 16, wherein the intensity of the first and second portions of the radiation is determined a plurality of times at a sampling frequency.
